(19) United States
(12) Patent Application Publication
(10) Pub. No.: US 2006/0147812 A1
(43) Pub. Date: Jul. 6, 2006

(54) METHOD AND SYSTEM FOR MEASURING CRITICAL DIMENSIONS OF A MASK DESIGN PATTERN

(76) Inventors: Ming-Feng Ho, Hsin-Chu City (TW); Hua-Jen Chen, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 10/905,427

(22) Filed: Jan. 4, 2005

(51) Int. Cl. G06F 17/50; G03F 1/00; G03C 5/00

(52) U.S. Cl. 430/5; 716/19; 716/21; 430/30

(57) ABSTRACT

The present invention provides a method and a system for measuring critical dimensions of a mask design pattern. The method includes: setting up a server comprising a measure system; establishing a connection between the server and a remote terminal through the Internet; and utilizing the remote terminal to login the server so as to transmit the mask design pattern to the server and remotely control the measure system to measure the critical dimensions of the mask design pattern.

### BACKGROUND OF INVENTION

1. Field of the Invention

The present invention relates to a method and a system for measuring critical dimensions of a mask design pattern, and more specifically, to a method and a system for remotely measuring critical dimensions of a mask design pattern.

2. Description of the Prior Art

In the semiconductor field, during fabrication, all elements must go through a series of processes, and one of the key processes is lithography, which transfers integrated circuit (IC) layouts onto semiconductor chips. Generally, a semiconductor-manufacturing company designs several mask design patterns according to the IC layouts and then asks mask-manufacturing companies to fabricate masks according to the mask design patterns. Consequently, the patterns on the masks are transferred to the photoresists of the semiconductor chips with a predetermined ratio through lithography.

Similarly, in the photoelectronic field, during fabrication, all elements must go through a series of processes, and one of the key processes is lithography, which transfers photoelectronic circuit layouts onto photoelectronic bases (e.g. the base of thin film transistor liquid crystal displays and the glass base of color filters). Generally, a manufacturing company of photoelectronic devices designs several mask design patterns according to the photoelectronic circuit layouts and then asks mask-manufacturing companies to fabricate masks according to the mask design patterns. Consequently, the patterns on the masks are transferred to the photoresists of the photoelectronic bases with a predetermined ratio through lithography. Moreover, not only in the photoelectronic field, the printed circuit board (PCB) industry also has similar applications.

As the integration of IC and photoelectronic circuits advances, the pattern design of the mask becomes smaller and smaller. When manufacturing the mask, the mask-manufacturing company must control the critical dimension of the mask design pattern precisely so as to transfer the complicated and detailed mask design patterns correctly to real masks. Generally, after receiving an order, the mask-manufacturing company receives the mask design patterns from the client. The mask design patterns are designed according to the IC layouts or photoelectronic circuit layouts, so the mask design patterns correspond to the size and location of the devices. In some IC layouts or photoelectronic circuit layouts, particularly if there are some devices which are extremely important or if some portions of the layouts have extremely tight and complicated line configurations, when giving the mask-manufacturing company the mask design patterns, the client will also offer partial zoom-in pictures of the portions. As a result, the mask-manufacturing company can find out the critical dimensions of the mask design patterns by measuring the partial zoom-in pictures of the portions, and then pass the obtained information to manufacturing staff for further setting the conditions of the mask-manufacturing process.

However, for mask-manufacturing companies, merely the mask design pattern and partial zoom-in pictures of key portions are not enough because although the mask-manufacturing company can get the critical dimensions by measuring the partial zoom-in pictures of key portions, the locations of the key portions on the mask design pattern are still unknown. Therefore, the mask-manufacturing company has to find out the locations of the key portions throughout the mask design pattern. This step takes much time, and as the person who takes the measurements in the mask-manufacturing company is not the designer of the mask design pattern, the found key portions or the measured critical dimensions of the mask design pattern may not totally correspond to the original intention of the designer. In this situation, the client and the mask-manufacturing company must have more communication via emails or telephone calls so that the original intention of the designer can be correctly passed on to the measuring person in the mask-manufacturing company. This process not only leads to inconvenience but also decreases the yield efficiency of the mask.

### SUMMARY OF INVENTION

It is therefore a primary objective of the claimed invention to provide a method and a system for measuring the critical dimensions of the mask design pattern to solve the above-mentioned problem.

According to the claimed invention, a method for measuring the critical dimensions of the mask design pattern is disclosed. The method includes: setting up a server comprising a measure system; establishing a connection between the server and a remote terminal through the Internet; and utilizing the remote terminal to login the server so as to transmit the mask design pattern to the server and remotely control the measure system to measure the critical dimensions of the mask design pattern.

In addition, the claimed invention provides a system for measuring critical dimensions of a mask design pattern. The system includes: a server comprising a measure system which is utilized for measuring the critical dimension of the mask design pattern; and a remote terminal coupled to the server through the Internet for transmitting the mask design pattern to the server and remotely controlling the measure system to measure the critical dimensions of the mask design pattern.

According to the system and the method provided by the present invention, the client can use a remote terminal to login the server provided by the mask-manufacturing company through the Internet, and further remotely control the measure system to measure the critical dimensions of the mask design pattern. Then the operator in the mask-manufacturing company can make the mask according to the measure results given by the client. As a result, human resources and measuring time can be enormously saved by taking advantage of the present invention.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a block diagram of a first embodiment of a critical dimension measure system according to the present invention.

FIG. 2 is a block diagram of a second embodiment of a critical dimension measure system according to the present invention.

### DETAILED DESCRIPTION

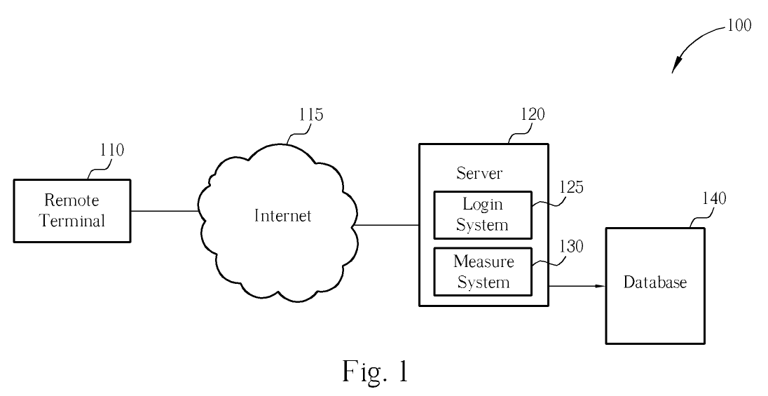

The present invention provides a method and its corresponding system to solve the problem encountered in the prior art. FIG. 1 shows the first embodiment of the present invention, the critical dimension measure system 100. In the critical dimension measure system 100, the mask-manufacturing company itself sets up a server 120, and the client can use a remote terminal 110 to connect the server 120 through the Internet 115. The server 120 is installed with a login system 125 and a measure system 130 for measuring the critical dimensions of the mask design patterns. After being ordered by the client, the mask-manufacturing company initially sets the login data such as username and password in the login system 125, and then the client can access the login system 125 by inputting the login data on the remote terminal 110. The login system 125 is used for preventing the client's data from being stolen. The client has to input correct login data in the login system 125 to conform to the security rules of the login system 125 so that the client can login the server 120 successfully. After the client successfully logs in the server 120, the client can transmit the mask design pattern to the server through the Internet 115, and then utilize the remote terminal 110 to control the measure system 130 in the server 120. The measure result is stored in the database 140 which can be accessed by the manufacturing staff. Please note that the login system 125 and the measure system 130 are displayed in web pages; therefore, only a regular web browser is needed on the remote terminal 110 to connect the login system 125 or to use the measure system 130. According to the disclosed measure system 100 of the present invention, since the client himself is the designer of the mask design pattern, instead of the mask being searched and measured by the measuring person of the mask-manufacturing company, the key portions of the mask design pattern can be found and the critical dimension can be further measured quickly and correctly by the client himself by controlling the measure system 130. As a result, by using the system and method disclosed by the present invention, mistakes due to insufficient communication between the client and the mask-manufacturing company can be greatly minimized, and the mask-manufacturing company can save human resources so that the mask manufacturing process can be smoother and the cost decreased.

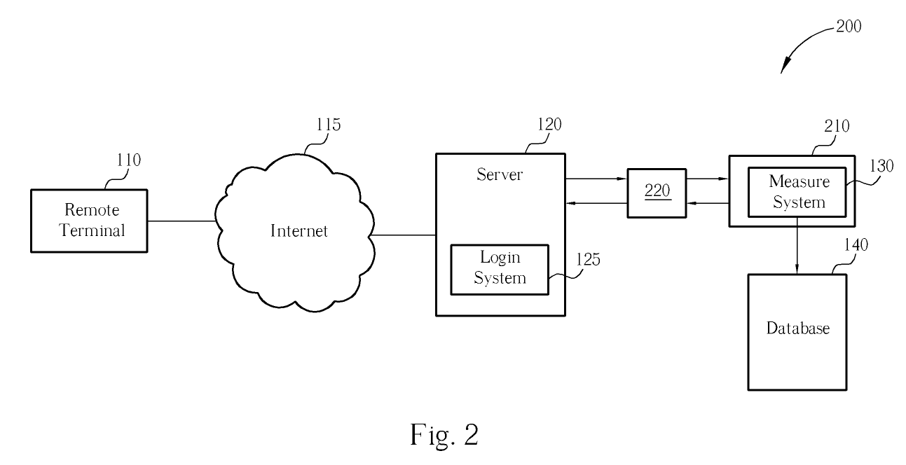

Moreover, in order to protect the client's data more carefully, another embodiment of the present invention is disclosed. FIG. 2 shows the second embodiment of the present invention, the critical dimension measure system 200. The difference between FIGS. 1 and 2 is that an extra host 210 and a firewall 220 coupled between the host 210 and the server 120 are presented, and the measure system originally set in the server 120 is moved to the host 210. Please note that the same elements that show up in both FIGS. 1 and 2 have the same functions, so a lengthy description is omitted for the sake of brevity. In this embodiment, the mask-manufacturing company sets up the firewall 220 for setting up a separation between the local area network of the mask-manufacturing company and the Internet 115. The measure system 130 is moved from the server 120 to the host 210 located in the local area network protected by the firewall 220; therefore, the strict security mechanism provided by the firewall 220 can further limit the authority to access the host 210 of the Internet users. As a result, after the client logs in the server 120 through the validation of the login system 125, the client can transmit the mask design pattern to the host 210 through the Internet 115 and the server 120. Then, by taking advantage of the command transmitted back and forth between the server 120 and the host 210, the client can remotely control the measure system 130 to complete the search of key portions and the measurement of critical dimensions. Finally, the measured critical dimensions can then be stored in a database 140 to be accessed by the manufacturing staff.

In the mask-manufacturing process, the main reason for the inefficiency of the manufacturing process is the mistakes due to insufficient communication between the client and the mask-manufacturing company. Consequently, the present invention provides a method and corresponding system for measuring the critical dimensions of the mask design pattern so that the client can simply use a web browser on a remote terminal to control the measure system offered by the mask-manufacturing company. The precise key portions and critical dimensions can be given by the client himself; therefore, the mistakes can be greatly reduced and the mask-manufacturing company can save human resources.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for measuring critical dimensions of a mask design pattern, comprising:
setting up a server comprising a measure system;
establishing a connection between the server and a remote terminal through the Internet; and
utilizing the remote terminal to login the server so as to transmit the mask design pattern to the server and remotely control the measure system to measure the critical dimensions of the mask design pattern.

2. The method of claim 1 further comprising:
providing a login system in the server; and
utilizing the login system for determining whether the remote terminal can login the server according to security rules;
wherein if login data inputted by the remote terminal into the login system conforms to the security rules, the login system allows the remote terminal to login the server.

3. The method of claim 1 further comprising:
setting up a database for storing the critical dimensions.

4. The method of claim 1, wherein an interface of the measure system is a web page.

5. A system for measuring critical dimensions of a mask design pattern, comprising:
a server comprising a measure system which is utilized for measuring the critical dimensions of the mask design pattern; and
a remote terminal coupled to the server through the Internet for transmitting the mask design pattern to the server and remotely controlling the measure system to measure the critical dimensions of the mask design pattern.

6. The system of claim 5, wherein the server further comprises:
a login system for determining whether the remote terminal can login the server according to security rules;
wherein if login data inputted by the remote terminal into the login system conforms to the security rules, the login system allows the remote terminal to login the server.

7. The system of claim 5 further comprising:
a database for storing the critical dimensions.

8. The system of claim 5, wherein an interface of the measure system is a web page.

9. A method for measuring critical dimensions of a mask design pattern, comprising:
setting up a server and a host, wherein the host comprises a measure system;
providing a security mechanism for ensuring that only the server can be connected to the host and control the measure system;
establishing a connection between the server and a remote terminal through the Internet; and
utilizing the remote terminal to login the server so as to transmit the mask design pattern to the host and remotely control the measure system to measure the critical dimensions of the mask design pattern through the server.

10. The method of claim 9, wherein the security mechanism is provided by a firewall.

11. The method of claim 9 further comprising:
providing a login system in the server; and
utilizing the login system for determining whether the remote terminal can login the server according to security rules;
wherein if login data inputted by the remote terminal into the login system conforms to the security rules, the login system allows the remote terminal to login the server.

12. The method of claim 9 further comprising:
setting up a database for storing the critical dimensions.

13. The method of claim 9, wherein an interface of the measure system is a web page.

14. A system for measuring critical dimensions of a mask design pattern, comprising:
a server;
a host coupled to the server through a security mechanism and having a measure system, wherein the measure system is utilized for measuring the critical dimensions of the mask design pattern and the security mechanism is utilized for ensuring that only the server can be connected to the host and control the measure system; and
a remote terminal coupled to the server through the Internet for transmitting the mask design pattern to the host and remotely controlling the measure system to measure the critical dimensions of the mask design pattern through the server.

15. The system of claim 14, wherein the security mechanism is a firewall.

16. The system of claim 14, wherein the server comprises:
a login system for determining whether the remote terminal can login the server according to security rules;
wherein if login data inputted by the remote terminal into the login system conforms to the security rules, the login system allows the remote terminal to login the server.

17. The system of claim 14 further comprising:
a database for storing the critical dimensions.

18. The system of claim 14, wherein an interface of the measure system is a web page.
